(19) United States
(12) Patent Application Publication
(10) Pub. No.: US 2026/0164949 A1
(43) Pub. Date: Jun. 11, 2026

(54) DISPLAY DEVICE, AND ELECTRONIC DEVICE INCLUDING THE SAME

(71) Applicant: Samsung Display Co., Ltd., Yongin-Si (KR)

(72) Inventor: Kee Bum PARK, Yongin-si (KR)

(21) Appl. No.: 19/179,341

(22) Filed: Apr. 15, 2025

(30) Foreign Application Priority Data
Jun. 21, 2024 (KR) 10-2024-0081216
Sep. 10, 2024 (KR) 10-2024-0123309

(51) Int. Cl. H10K 59/124; H10K 59/122; H10K 59/35

(52) U.S. Cl. CPC H10K 59/124; H10K 59/122; H10K 59/35

(57) ABSTRACT

A display device includes an organic film layer having a plurality of inclined surfaces including a first inclined surface and a second inclined surface, a first light-emitting element disposed on the first inclined surface, and a second light-emitting element disposed on the second inclined surface. The first light-emitting element and the second light-emitting element emit light of the same color, and the first light-emitting element is symmetrical to the second light-emitting element with respect to a first pixel definition layer disposed on the organic film layer.

### CROSS-REFERENCE TO RELATED APPLICATION

This application claims priority to and the benefit of Korean Patent Application No. 10-2024-0081216 filed in the Korean Intellectual Property Office on Jun. 21, 2024 and Korean Patent Application No. 10-2024-0123309 filed in the Korean Intellectual Property Office on Sep. 10, 2024, the entire contents of which are incorporated herein by reference.

### BACKGROUND

### (a) Field

The present disclosure relates to a display device, and electronic device including the same.

### (b) Description of the Related Art

A display device may include a display panel that displays an image, a window displayed on the display panel, and a functional panel that is interposed between the display panel and the window and receives a touch input or prevents reflection of external light.

The display panel may include a light-emitting element, and the light emitted from the light-emitting element may pass through the functional panel and the window to be emitted toward a front surface of the display device.

In this case, as technology develops, an automobile that goes beyond a simple transportation apparatus may include various display devices. Through the display device, various types of information, such as real-time traffic information and the current state of a vehicle, may be obtained.

However, when the light emitted from the display device is reflected on a windshield of the automobile, a driver's vision may be obstructed. In order to prevent the driver's vision from being obstructed, a light control film, which may limit an emission angle of the light emitted from a display device, is being used.

The above description is only intended to help understand the background technology for the technical ideas of the present disclosure, and accordingly, the above description may not be understood as content corresponding to the prior art known to those skilled in the art in the technical field of the present disclosure.

### SUMMARY

The present disclosure provides a display device that prevents unintended light from being output and a method of manufacturing the display device.

An embodiment provides a display device including an organic film layer having a plurality of inclined surfaces including a first inclined surface and a second inclined surface; a first light-emitting element disposed on the first inclined surface; and a second light-emitting element disposed on the second inclined surface. The first light-emitting element and the second light-emitting element emit light of the same color, and the first light-emitting element is symmetrical to the second light-emitting element with respect to a first pixel definition layer disposed on the organic film layer.

The organic film layer may have a trapezoidal shape in cross-section.

A normal direction of the first inclined surface of the organic film layer may be different from a normal direction of the second inclined surface of the organic film layer.

In a period in which the first light-emitting element emits the light, the second light-emitting element may not emit the light.

The first light-emitting element may be included in a first sub-pixel, and the second light-emitting element may be included in a second sub-pixel different from the first sub-pixel.

An embodiment provides a display device including an organic film layer having a plurality of inclined surfaces including a first inclined surface and a second inclined surface; a first light-emitting element disposed on the first inclined surface and the second inclined surface; a first shield voltage layer disposed on a first area of the first light-emitting element; and a second shield voltage layer disposed on a second area of the first light-emitting element. Voltages are individually applied to the first shield voltage layer and the second shield voltage layer.

The organic film layer may have a trapezoidal shape in cross-section.

The display device may further include a first pixel definition layer and a second pixel definition layer. The first shield voltage layer may be disposed on the first pixel definition layer and the first area of the first light-emitting element, and the second shield voltage layer may be disposed on the second pixel definition layer and the second area of the first light-emitting element.

A normal direction of an upper surface of the first shield voltage layer disposed on the first area of the first light-emitting element may be different from a normal direction of an upper surface of the second shield voltage layer disposed on the second area of the first light-emitting element.

The first light-emitting element may include a first electrode disposed on the organic film layer. The same voltage is applied to the first electrode and the first shield voltage layer, and the second shield voltage layer may be in a floating state.

An embodiment provides a method of manufacturing a display device including a first light-emitting element including an 11th electrode, a first functional layer, and a 12th electrode, and a second light-emitting element including a 21st electrode, a second functional layer, and a 22nd electrode. The method includes forming an organic film layer having a plurality of inclined surfaces including a first inclined surface and a second inclined surface; forming the 11th electrode on the first inclined surface and the 21st electrode on the second inclined surface; forming a first pixel definition layer on the organic film layer; forming the first functional layer on the 11th electrode and forming the second functional layer on the 21st electrode; and forming the 12th electrode on the first functional layer and forming the 22nd electrode on the second functional layer. The first light-emitting element and the second light-emitting element emit light of the same color, and the first light-emitting element is symmetrical to the second light-emitting element with respect to the first pixel-definition layer.

The organic film layer may have a trapezoidal shape in cross-section.

A normal direction of the first inclined surface of the organic film layer may be different from a normal direction of the second inclined surface of the organic film layer.

The method may further include forming a circuit layer; and forming a second pixel-definition layer and a third pixel-definition layer on the circuit layer after the forming of the 11th electrode and the 21st electrode. The second pixel-definition layer is symmetrical to the third pixel-definition layer with respect to the first pixel-definition layer.

The first light-emitting element may be included in a first sub-pixel, and the second light-emitting element may be included in a second sub-pixel that is different from the first sub-pixel.

An embodiment provides a method of manufacturing a display device, the method includes forming an organic film layer; forming a first light-emitting element on the organic film layer; forming a first shield voltage layer on a first area of the first light-emitting element; and forming a second shield voltage layer on a second area of the first light-emitting element. Voltages are individually applied to the first shield voltage layer and the second shield voltage layer.

In the forming of the organic film layer, the organic film layer may have a trapezoidal shape in cross-section.

The method may further include forming a first pixel definition layer and a second pixel definition layer. The first shield voltage layer may be disposed on the first pixel definition layer and the first area of the first light-emitting element, and the second shield voltage layer may be disposed on the second pixel definition layer and the second area of the first light-emitting element.

A normal direction of an upper surface of the first shield voltage layer disposed on the first area of the first light-emitting element may be different from a normal direction of an upper surface of the second shield voltage layer disposed on the second area of the first light-emitting element.

The first light-emitting element may include a first electrode disposed on the organic film layer. The same voltage is applied to the first electrode and the first shield voltage layer, and the second shield voltage layer may be in a floating state.

According to embodiments of the present disclosure, a display device that prevents unintended light from being output and a method of manufacturing the display device may be provided.

Effects according to the embodiments are not limited to the descriptions exemplified above, and more diverse effects are included in the present disclosure.

### BRIEF DESCRIPTION OF THE DRAWINGS

FIG. 1 is a view illustrating a display device according to an embodiment of the present disclosure.

FIG. 2 is a plan view of the display device of FIG. 1, according to an embodiment.

FIG. 3 is a cross-sectional view illustrating an embodiment of a display device which is taken along line I-I′ of FIG. 2.

FIG. 4 is a view illustrating an embodiment of the display device of FIG. 3.

FIG. 5 is a plan view of a display device of FIG. 1 according to an embodiment.

FIG. 6 is a cross-sectional view illustrating an embodiment of a display device which is taken along line II-II′ of FIG. 5.

FIG. 7 is a view illustrating an embodiment of the display device of FIG. 6.

FIG. 8 is a flowchart illustrating a method of manufacturing the display device of FIG. 1.

FIG. 9 is a flowchart of step S830 of FIG. 8, according to an embodiment.

FIG. 10 is a view illustrating step S910 of FIG. 9.

FIG. 11 is a view illustrating step S920 of FIG. 9.

FIG. 12 is a view illustrating step S930 of FIG. 9.

FIG. 13 is a view illustrating step S940 of FIG. 9.

FIG. 14 is a view illustrating step S950 of FIG. 9.

FIG. 15 is a flowchart illustrating step S830 of FIG. 8, according to an embodiment.

FIG. 16 is a block diagram of an electronic device according to an embodiment.

FIG. 17 shows schematic views of various embodiments of an electronic device.

### DETAILED DESCRIPTION OF THE EMBODIMENTS

Hereinafter, example embodiments of the present disclosure will be described in detail with reference to the accompanying drawings. The following description is intended to provide only a sufficient disclosure to enable the understanding of the operation of the inventive concept, and any other disclosure is omitted to avoid obscuring the scope of the inventive concept. In addition, the inventive concept may be embodied in different forms and is not limited to the embodiments set forth herein. The embodiments described herein are provided for the purpose of describing the technical concept of the inventive concept in sufficient detail for those skilled in the art to easily practice it.

Throughout the specification, when it is described that an element is “connected” to another element, this includes not only being “directly connected”, but also being “indirectly connected” with another device therebetween. The terms used herein are for the purpose of describing specific embodiments and are not intended to limit the scope of the inventive concept. Throughout the specification, unless explicitly described to the contrary, the word “comprise” and variations such as “comprises” or “comprising” will be understood to imply the inclusion of stated elements but not the exclusion of any other elements. For the purposes of this disclosure, “at least one of X, Y, and Z” and “at least one selected from the array consisting of X, Y, and Z” may be construed as X only, Y only, Z only, or any combination of two or more of X, Y, and Z, such as, for instance, XYZ, XYY, YZ, and ZZ. As used herein, the term “and/or” includes any and all combinations of one or more of the associated listed items.

Although the terms first, second, etc. may be used herein to describe various constituent elements, these constituent elements should not be limited by these terms. These terms are used to distinguish one constituent element from another. Thus, a first constituent element discussed below could be termed a second constituent element without departing from the teachings of the present disclosure.

Spatially relative terms, such as “beneath,” “below,” “lower,” “above,” “upper,” and the like, may be used herein for descriptive purposes, and, thereby, to describe one element or feature's relationship to another element(s) or feature(s) as illustrated in the drawings. Spatially relative terms are intended to encompass different orientations of an apparatus in use, operation, and/or manufacture in addition to the orientation depicted in the drawings. For example, if the apparatus in the drawings is turned over, elements described as “below” or “beneath” other elements or features would then be oriented “above” the other elements or features. Thus, the term “below” can encompass both an orientation of above and below. Furthermore, the apparatus may be otherwise oriented (for example, rotated 90 degrees or at other orientations), and, as such, the spatially relative descriptors used herein interpreted accordingly.

Various embodiments are described herein with reference to sectional illustrations that are schematic illustrations of idealized embodiments. As such, variations from the shapes of the illustrations as a result, for example, of manufacturing techniques and/or tolerances, are to be expected. Thus, exemplary embodiments disclosed herein should not be construed as limited to the particular illustrated shapes of regions, but are to include deviations in shapes that result from, for instance, manufacturing. Thus, the regions illustrated in the drawings are schematic in nature and their shapes are not intended to illustrate the actual shape of a region of a device and are not intended to be limiting.

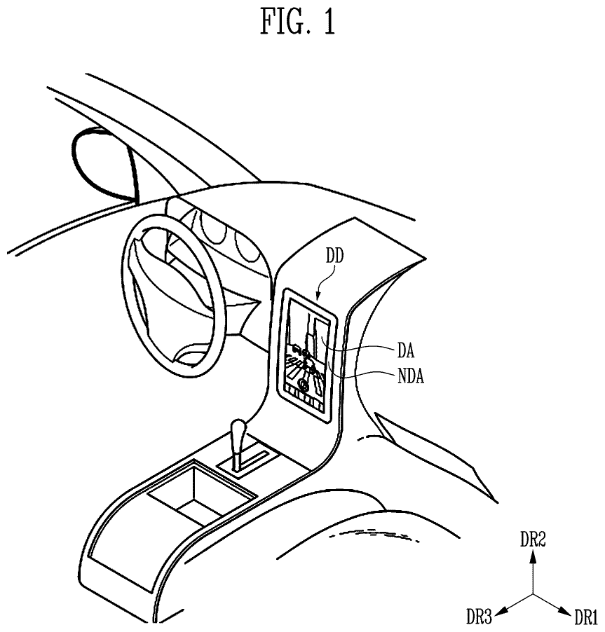

FIG. 1 is a view illustrating a display device DD according to an embodiment of the present disclosure.

Referring to FIG. 1, the display device DD may be a vehicle information guide display (a center information display: CID). The display device DD may be activated according to an electrical signal. The display device DD may include various embodiments. For example, the display device DD may be provided to a transportation apparatus, such as an automobile, a bicycle, a motorcycle, a ship, an airplane, or so on. In addition, the display device DD may be applied to large electronic devices, such as a television, a monitor, and an electronic scoreboard, as well as small and medium-sized electronic devices, such as a tablet, a navigation device, a game console, and a smart watch. In addition, the display device DD may also be applied to a wearable electronic device, such as a head-mounted display. These are examples, and the display device DD may be employed as another display device as long as the display device DD does not deviate from the concept of the present disclosure.

The display device DD may include a display area DA and a non-display area NDA. The display area DA may be an area where an image is displayed. In FIG. 1, a traffic situation is illustrated as an example of an image. The non-display area NDA may be an area where an image is not displayed. The display area DA may be parallel to a plane defined by a first direction DR1 and a second direction DR2 intersecting the first direction DR1.

Herein, an upper surface (or front surface) and a lower surface (or rear surface) of each member are defined in a direction in which images are displayed. The upper surface faces the lower surface face in a third direction DR3, and a normal direction of each of the upper surface and the lower surface may be parallel to the third direction DR3.

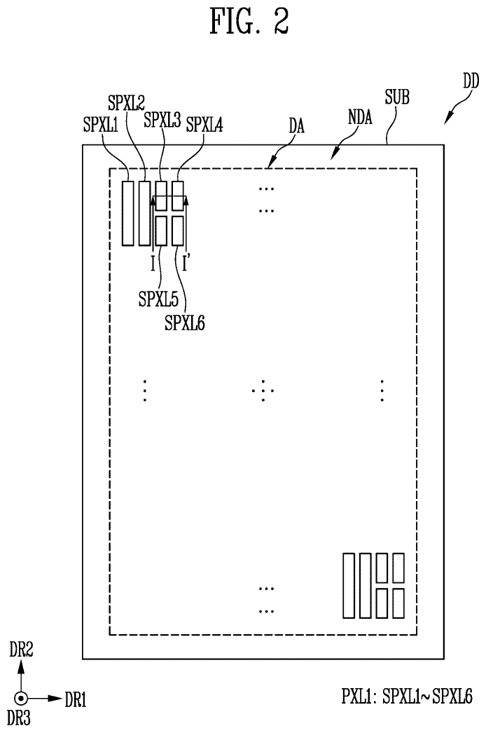

FIG. 2 is a plan view of the display device DD of FIG. 1 according to an embodiment.

Referring to FIG. 2, the display device DD including a base layer SUB may include the display area DA for displaying an image, and the non-display area NDA excluding the display area DA. The display area DA may constitute a screen on which an image is displayed, and the non-display area NDA may be the other area excluding the display area DA.

For the sake of convenience of description, a structure of the display device DD is briefly illustrated in FIG. 2 mainly for the display area DA. However, although not illustrated in FIG. 2, at least one drive circuit (for example, at least one of a scan drive unit and a data drive unit), wires, and/or pads may be further disposed in the display device DD.

First pixels PXL1 may be disposed in the display area DA. The first pixels PXL1 may each include a first sub-pixel SPXL1 to a sixth sub-pixel SPXL6. In FIG. 2, for the sake of clear and concise description, the first sub-pixel SPXL1 to the sixth sub-pixel SPXL6 included in one first pixel PXL1 are illustrated. It may be understood that each of the other first pixels PXL1 also includes the first sub-pixel SPXL1 to the sixth sub-pixel SPXL6.

The first pixels PXL1 may be arranged regularly according to a stripe, a PENTILE™ arrangement structure, or so on. Here, the arrangement structure of the first pixels PXL1 is not limited thereto, and the first pixels PXL1 may be arranged in the display area DA in various structures and/or methods.

The first sub-pixel SPXL1 and the second sub-pixel SPXL2 may emit light of a first color. The third sub-pixel SPXL3 and the fourth sub-pixel SPXL4 may emit light of a second color. The fifth sub-pixel SPXL5 and the sixth sub-pixel SPXL6 may emit light of a third color.

At least one of the first to sixth sub-pixels SPXL1 to SPXL6 disposed adjacent to each other may constitute the first pixel PXL1 that may emit light of various colors. For example, the first and second sub-pixels SPXL1 and SPXL2 may be red pixels that emit red light, the third and fourth sub-pixels SPXL3 and SPXL4 may be green pixels that emit green light, and the fifth and sixth sub-pixels SPXL5 and SPXL6 may be blue pixels that emit blue light but are not limited thereto.

In the embodiments, the display device DD may support a first mode in which the first, third, and fifth sub-pixels SPXL1, SPXL3, and SPXL5 are selected to emit light, and a second mode in which the second, fourth, and sixth sub-pixels SPXL2, SPXL4, and SPXL6 are selected to emit light. In the first mode, the first, third, and fifth sub-pixels SPXL1, SPXL3, and SPXL5 of each of the first pixels PXL1 may emit light to display an image. In the second mode, the second, fourth, and sixth sub-pixels SPXL2, SPXL4, and SPXL6 of each of the first pixels PXL1 may emit light to display an image.

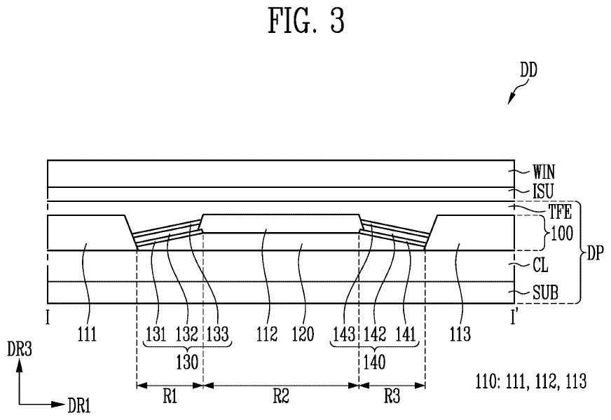

FIG. 3 is a cross-sectional view illustrating an embodiment of the display device DD which is taken along line I-I′ of FIG. 2.

Referring to FIG. 3, the display device DD may include a display panel DP, an input sensing layer ISU, and a window WIN.

The display panel DP may include a base layer SUB, a circuit layer CL, a display element layer 100, and an encapsulation layer TFE. In the embodiment of the present disclosure, the display panel DP may be an organic light-emitting display panel or a quantum dot display panel. A light-emitting layer of the organic light-emitting display panel may include an organic light-emitting material. A light-emitting layer of the quantum dot light-emitting display panel may include quantum dots and so on. However, this is an example, and the type of the display panel DP is not limited thereto.

The base layer SUB may be a polymer substrate, a plastic substrate, a glass substrate, a quartz substrate, or so on. The base layer SUB may be a transparent insulating substrate. The base layer SUB may be rigid. The base layer SUB may be flexible.

The circuit layer CL is disposed on the base layer SUB, and the circuit layer CL may include a plurality of transistors, and the plurality of transistors may each include a control electrode, an input electrode, and an output electrode. For example, the circuit layer CL may include a switching transistor and a drive transistor for driving first and second light-emitting elements 130 and 140 of the display element layer 100.

The display element layer 100 may include pixel definition layers 110, an organic film layer 120, and the first and second light-emitting elements 130 and 140. The pixel definition layers 110 may include an 11th pixel definition layer 111, a 12th pixel definition layer 112, and a 13th pixel definition layer 113.

An area where light-emitting elements are to be disposed may be divided by the pixel definition layers 110. The pixel definition layers 110 may each be formed by including a polyacrylate-based resin or a polyimide-based resin. In contrast to this, the pixel definition layers 110 may each be formed of an inorganic material. For example, the pixel definition layers 110 may each be formed by including silicon nitride, silicon oxide, silicon oxynitride, or so on.

The pixel definition layers 110 may have various shapes as illustrated in FIG. 3. For example, the 11th pixel definition layer 111 and the 13th pixel definition layer 113 may each have a trapezoidal shape in cross-section. For example, the 12th pixel definition layer 112 may have a rectangular shape in cross-section. A shape of each of the pixel definition layers 110 is not limited to the shape illustrated in FIG. 3.

The 11th pixel definition layer 111 may be disposed on the circuit layer CL. The 13th pixel definition layer 113 may be disposed on the circuit layer CL. The 11th pixel definition layer 111 and the 13th pixel definition layer 113 may be separated from each other in the first direction DR1. The 11th pixel definition layer 111 may be symmetrical to the 13th pixel definition layer 113 with the 12th pixel definition layer 112 therebetween.

In addition, the 12th pixel definition layer 112 may be disposed on the organic film layer 120. More specifically, the 12th pixel definition layer 112 may be disposed on a second region R2 of the organic film layer 120.

The organic film layer 120 may be disposed on the circuit layer CL. The organic film layer 120 may be formed of an organic material. The organic film layer 120 may have a plurality of inclined surfaces. In embodiments, the organic film layer 120 may have a trapezoidal shape in cross-section.

In this case, as illustrated in FIG. 3, the organic film layer 120 may include first, second, and third regions R1, R2, and R3. The first and third regions R1 and R3 of the organic film layer 120 may each include an inclined surface.

A normal direction of the inclined surface included in the first region R1 of the organic film layer 120 may be different from a normal direction of the inclined surface included in the third region R3 of the organic film layer 120. For example, as illustrated in FIG. 3, the normal direction of the inclined surface included in the first region R1 of the organic film layer 120 may face the left. The normal direction of the inclined surface included in the third region R3 of the organic film layer 120 may face the right.

The first light-emitting element 130 may include an 11th electrode 131, a first functional layer 132, and a 12th electrode 133 that are sequentially stacked. The 11th electrode 131 may be disposed on the inclined surface included in the first region R1 of the organic film layer 120. The 11th electrode 131 may be an anode electrode of the first light-emitting element 130, and the 12th electrode 133 may be a cathode electrode of the first light-emitting element 130. The first light-emitting element 130 may be included in the third sub-pixel SPXL3 (see FIG. 2).

The second light-emitting element 140 may include a 21st electrode 141, a second functional layer 142, and a 22nd electrode 143 that are sequentially stacked. The 21st electrode 141 may be disposed on an inclined surface included in the third region R3 of the organic film layer 120. The 21st electrode 141 may be an anode electrode of the second light-emitting element 140, and the 22nd electrode 143 may be a cathode electrode of the second light-emitting element 140. The second light-emitting element 140 may be included in the fourth sub-pixel SPXL4 (see FIG. 2).

The first functional layer 132 and the second functional layer 142 may each include a hole transfer region, an emission layer, and an electron transfer region that are sequentially stacked. The first light-emitting element 130 and the second light-emitting element 140 may emit light in the same wavelength range. The first light-emitting element 130 and the second light-emitting element 140 may emit light in a different wavelength range from the light-emitting elements included in the first and second sub-pixels SPXL1 and SPXL2 of FIG. 2. Similarly, the first light-emitting element 130 and the second light-emitting element 140 may emit light of in a different wavelength range from the light-emitting elements included in the fifth and sixth sub-pixels SPXL5 and SPXL6 of FIG. 2.

In the display element layer 100, the first and second light-emitting elements 130 and 140 may be distinguished by the pixel-definition layers 110. For example, a position of the first light-emitting element 130 may be defined by the 11th pixel-definition layer 111 and the 12th pixel-definition layer 112. For example, a position of the second light-emitting element 140 may be defined by the 12th pixel definition layer 112 and the 13th pixel definition layer 113.

The encapsulation layer TFE may be disposed on the display element layer 100 and seal the display element layer 100. The encapsulation layer TFE may protect the display element layer 100 from moisture and/or oxygen and may protect the display element layer (OEL) from foreign materials, such as dust particles. The encapsulation layer TFE may include at least one inorganic layer or at least one organic layer. The encapsulation layer TFE may have a structure in which organic layers and inorganic layers are alternately and repeatedly stacked. For example, the encapsulation layer TFE may have a structure in which an inorganic layer, an organic layer, and an inorganic layer are sequentially stacked.

According to an embodiment, the display device DD may further include the input sensing layer ISU disposed on the display panel DP. For example, the input sensing layer ISU may be disposed on the encapsulation layer TFE. The input sensing layer ISU detects an input applied from the outside. The input applied from the outside may be provided in various types. For example, an external input includes various types of external inputs, such as a part of a user's body, a stylus pen, light, heat, or pressure. In addition, an input with which a part of a user's body, such as a hand, comes into contact, as well as a close or adjacent space touch (for example, hovering), may be a type of the input.

The window WIN may be disposed on the input sensing layer ISU. For example, the window WIN may be disposed on the input sensing layer ISU to protect an upper surface of the display device DD.

According to the embodiment, an optical layer may be disposed between the window WIN and the input sensing layer ISU. Accordingly, the input sensing layer ISU may be separated from the window WIN. For example, an upper surface of the input sensing layer ISU may be separated from the window WIN without being in contact with each other.

The window WIN may include an optically transparent insulating material. For example, the window WIN may include glass or plastic. In addition, the window WIN may have a multilayer structure or a single layer structure. For example, the window WIN may include multiple plastic films bonded to each other by an adhesive or may include a glass substrate and a plastic film bonded to each other by an adhesive.

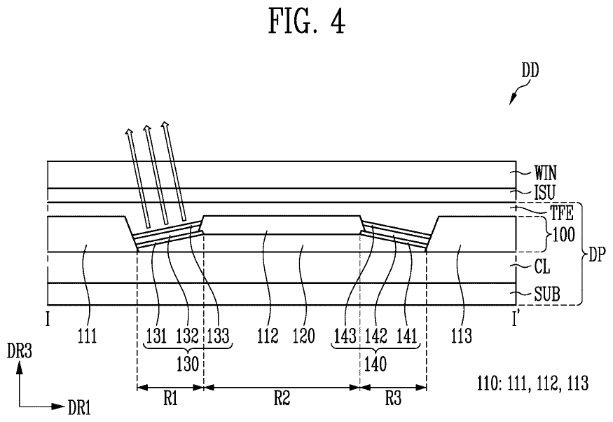

FIG. 4 is a view illustrating an embodiment of the display device DD of FIG. 3.

Referring to FIGS. 3 and 4, a normal direction of an inclined surface included in the first region R1 of the organic film layer 120 may be different from a normal direction of an inclined surface included in the third region R3 of the organic film layer 120. For example, as illustrated in FIG. 3, the normal direction of the inclined surface included in the first region R1 of the organic film layer 120 may face the left. The normal direction of the inclined surface included in the third region R3 of the organic film layer 120 may face the right.

Accordingly, the first light-emitting element 130 disposed on the inclined surface included in the first region R1 of the organic film layer 120 may emit light to the left. The second light-emitting element 140 disposed on the inclined surface included in the third region R3 of the organic film layer 120 may emit light to the right.

In embodiments of the present disclosure, the display device DD may emit light by selecting either the first light-emitting element 130 or the second light-emitting element 140. For example, the second light-emitting element 140 may emit light, and the first light-emitting element 130 may not emit light. Accordingly, light may be emitted to the right of the organic film layer 120, and light may not be emitted to the left of the organic film layer 120. For example, the first light-emitting element 130 may emit light, and the second light-emitting element 140 may not emit light. Accordingly, light may be emitted to the left of the organic film layer 120, and light may not be emitted to the right of the organic film layer 120.

As illustrated in FIGS. 3 and 4, the first light-emitting element 130 and the second light-emitting element 140 may be respectively disposed on different inclined surfaces of the organic film layer 120. In addition, only one of the first light-emitting element 130 and the second light-emitting element 140 may selectively emit light. Accordingly, a path of the light emitted from the display device DD may be controlled.

Although FIGS. 3 and 4 illustrate only the third and fourth sub-pixels SPXL3 and SPXL4 as examples, the same description may be applied to the other sub-pixels. For example, light-emitting elements of the first and second sub-pixels SPXL1 and SPXL2 of FIG. 2 may be respectively disposed on different inclined surfaces of a corresponding organic film layer, and a selected light-emitting element among the light-emitting elements may emit light. Light-emitting elements of the fifth and sixth sub-pixels SPXL5 and SPX6 of FIG. 2 may be respectively disposed on different inclined surfaces of a corresponding organic film layer, and a selected light-emitting element among the light-emitting elements may emit light. Accordingly, in the first mode in which the first, third, and fifth sub-pixels SPXL1, SPXL3, and SPXL5 emit light, an image may be provided generally to the left (or in a diagonal direction between the third direction DR3 and an opposite direction of the first direction DR1). In the second mode in which the second, fourth, and sixth sub-pixels SPXL2, SPXL4, and SPXL6 emit light, an image may be provided generally to the right (or in a diagonal direction between the third direction DR3 and the first direction DR1).

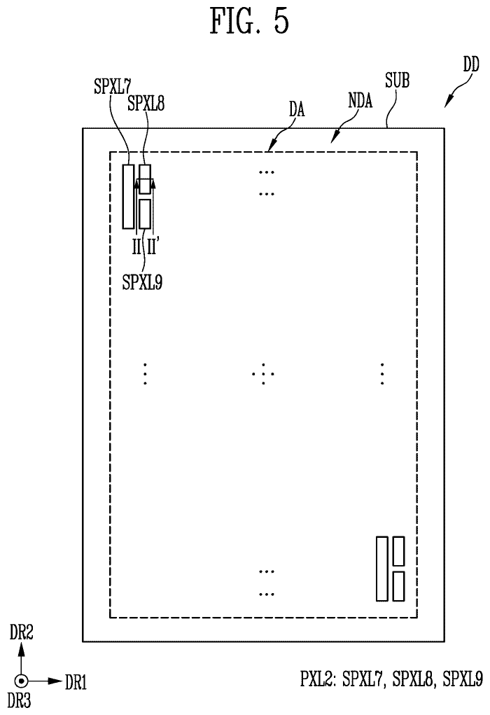

FIG. 5 is a plan view of a display device of FIG. 1 according to an embodiment.

Referring to FIG. 5, a display device DD including a base layer SUB may include a display area DA for displaying an image and a non-display area NDA excluding the display area DA. The display area DA may constitute a screen on which an image is displayed, and the non-display area NDA may be the other area excluding the display area DA.

For the sake of convenience of description, a structure of the display device DD is briefly illustrated in FIG. 5 mainly for the display area DA. However, although not illustrated in FIG. 5, at least one drive circuit (for example, at least one of a scan drive unit and a data drive unit), wires, and/or pads may be further disposed in the display device DD.

Second pixels PXL2 may be disposed in the display area DA. Each of the second pixels PXL2 may include a seventh sub-pixel SPXL7 to a ninth sub-pixel SPXL9. In FIG. 5, for the sake of clear and concise description, the seventh sub-pixel SPXL7 to the ninth sub-pixel SPXL9 included in one second pixel PXL2 are illustrated. It may be understood that each of the other second pixels PXL2 also include the seventh sub-pixel SPXL7 to the ninth sub-pixel SPXL9.

The second pixels PXL2 may be arranged regularly according to a stripe or a PENTILE™ arrangement structure or so on. However, the arrangement structure of the second pixels PXL2 is not limited thereto, and the second pixels PXL2 may be arranged in the display area DA in various structures and/or methods.

The seventh sub-pixel SPXL7 may emit light of a first color. The eighth sub-pixel SPXL8 may emit light of a second color. The ninth sub-pixel SPXL9 may emit light of a third color.

At least one of the seventh to ninth sub-pixels SPXL7 to SPXL9 disposed adjacent to each other may constitute the second pixel PXL2 that may emit light of various colors. For example, the seventh sub-pixel SPXL7 may be a red pixel that emits red light, the eighth sub-pixel SPXL8 may be a green pixel that emits green light, and the ninth sub-pixel SPXL9 may be a blue pixel that emits blue light but are not limited thereto.

In the embodiments, the display device DD may support a first mode that displays an image in a left direction in general, and a second mode that displays an image in a right direction in general. In the first mode, light-emitting elements of the seventh, eighth, and ninth sub-pixels SPXL7, SPXL8, and SPXL9 may be configured to emit light in a left direction in general to provide an image in the left direction. In the second mode, light-emitting elements of the seventh, eighth, and ninth sub-pixels SPXL7, SPXL8, and SPXL9 may be configured to emit light in a right direction in general to provide an image in the right direction.

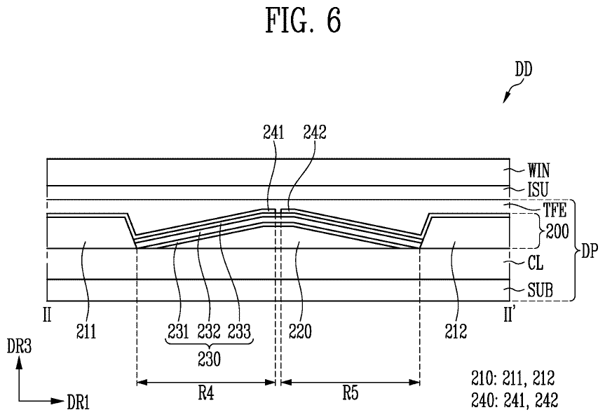

FIG. 6 is a cross-sectional view illustrating an embodiment of the display device DD which is taken along line II-II′ of FIG. 5.

Referring to FIG. 6, the display device DD may include a display panel DP, an input sensing layer ISU, and a window WIN.

The display panel DP may include a base layer SUB, a circuit layer CL, a display element layer 200, and an encapsulation layer TFE. In an embodiment of the present disclosure, the display panel DP may be an organic light-emitting display panel or a quantum dot display panel. A light-emitting layer of the organic light-emitting display panel may include an organic light-emitting material. A light-emitting layer of the quantum dot light-emitting display panel may include quantum dots and so on. However, this is an example, and the type of the display panel DP is not limited thereto.

The base layer SUB may be a polymer substrate, a plastic substrate, a glass substrate, a quartz substrate, or so on. The base layer SUB may be a transparent insulating substrate. The base layer SUB may be rigid. The base layer SUB may be flexible.

The circuit layer CL may be disposed on the base layer SUB, the circuit layer CL may include a plurality of transistors, and the transistors may each include a control electrode, an input electrode, and an output electrode. For example, the circuit layer CL may include a switching transistor and a drive transistor for driving a third light-emitting element 230 of the display element layer 200.

The display element layer 200 may include pixel definition layers 210, an organic film layer 220, the third light-emitting element 230, and a shield voltage layer 240. The pixel definition layers 210 may include a 21st pixel definition layer 211 and a 22nd pixel definition layer 212. The shield voltage layer 240 may include a first shield voltage layer 241 and a second shield voltage layer 242.

An area where the light-emitting element is to be disposed may be distinguished by the pixel definition layers 210. The pixel definition layers 210 may each be formed by including a polyacrylate-based resin or a polyimide-based resin. In contrast to this, the pixel definition layers 210 may each be formed by including an inorganic material. For example, the pixel definition layers 210 may each be formed by including silicon nitride, silicon oxide, silicon oxynitride, or so on.

The pixel definition layers 210 may have various shapes as illustrated in FIG. 6. For example, the 21st pixel definition layer 211 and the 22nd pixel definition layer 212 may each have a trapezoidal shape in cross-section. Shapes of the pixel definition layers 210 are not limited to the shapes Illustrated in FIG. 6.

The 21st pixel definition layer 211 may be disposed on the circuit layer CL. The 22nd pixel definition layer 212 may be disposed on the circuit layer CL. The 21st pixel definition layer 211 may be separated from the 22nd pixel definition layer 212 in the first direction DR1. The 21st pixel definition layer 211 may be symmetrical to the 22nd pixel definition layer 212 with the organic film layer 220 therebetween.

The organic film layer 220 may be disposed on the circuit layer CL. The organic film layer 220 may be formed of an organic material. The organic film layer 220 may have a plurality of inclined surfaces. In embodiments, the organic film layer 220 may have a trapezoidal shape in cross-section.

In this case, as illustrated in FIG. 6, the organic film layer 220 may include fourth and fifth regions R4 and R5. The fourth and fifth regions R4 and R5 of the organic film layer 220 may include inclined surfaces.

A normal direction of the inclined surface included in the fourth region R4 of the organic film layer 220 may be different from a normal direction of the inclined surface included in the fifth region R5 of the organic film layer 220. For example, as illustrated in FIG. 6, the normal direction of the inclined surface included in the fourth region R4 of the organic film layer 220 may face the left. The normal direction of the inclined surface included in the fifth region R5 of the organic film layer 220 may face the right.

The third light-emitting element 230 may include a 31st electrode 231, a third functional layer 232, and a 32nd electrode 233 that are sequentially stacked. The 31st electrode 231 may be disposed on the organic film layer 220. The 31st electrode 231 may be an anode electrode of the third light-emitting element 230, and the 32nd electrode 233 may be a cathode electrode of the third light-emitting element 230. The third functional layer 232 may include a hole transfer region, an emission layer, and an electron transfer region that are sequentially stacked.

In the display element layer 200, the third light-emitting element 230 may be distinguished by the pixel definition layers 210. For example, a position of the third light-emitting element 230 may be defined by the 21st pixel definition layer 211 and the 22nd pixel definition layer 212.

The first shield voltage layer 241 may be disposed on the 21st pixel definition layer 211 and the 32nd electrode 233. The second shield voltage layer 242 may be disposed on the 22nd pixel definition layer 212 and the 32nd electrode 233. More specifically, a part of the first shield voltage layer 241 may be disposed on an inclined surface included in the fourth region R4 of the organic film layer 220. A part of the second shield voltage layer 242 may be disposed on an inclined surface included in the fifth region R5 of the organic film layer 220.

The shield voltage layer 240 may include an inorganic material and a transparent electrode. The inorganic material of the shield voltage layer 240 electrically isolates the transparent electrode of the shield voltage layer 240, i.e., the first and second shield voltage layers 241, 242, from the 32nd electrode 233.

The encapsulation layer TFE may be disposed on the display element layer 200 to seal the display element layer 200. The encapsulation layer TFE may protect the display element layer 200 from moisture and/or oxygen and may protect the display element layer 200 from foreign materials, such as dust particles. The encapsulation layer TFE may include at least one inorganic layer or at least one organic layer. The encapsulation layer TFE may have a structure in which organic layers and inorganic layers are alternately and repeatedly stacked. For example, the encapsulation layer TFE may have a structure in which an inorganic layer, an organic layer, and another inorganic layer are sequentially stacked.

According to an embodiment, the display device DD may further include the input sensing layer ISU disposed on the display panel DP. For example, the input sensing layer ISU may be disposed on the encapsulation layer TFE. The input sensing layer ISU detects an input applied from the outside. The input applied from the outside may be provided in various types. For example, an external input includes various types of external inputs, such as a part of a user's body, a stylus pen, light, heat, or pressure. In addition, an input with which a part of a user's body, such as a hand, comes into contact, as well as a close or adjacent space touch (for example, hovering), may be a type of the input.

The window WIN may be disposed on the input sensing layer ISU. For example, the window WIN may be disposed on the input sensing layer ISU to protect an upper surface of the display device DD.

According to the embodiment, an optical layer may be disposed between the window WIN and the input sensing layer ISU. Accordingly, the input sensing layer ISU may be separated from the window WIN. For example, an upper surface of the input sensing layer ISU may be separated from the window WIN without being in contact with each other.

The window WIN may include an optically transparent insulating material. For example, the window WIN may include glass or plastic. In addition, the window WIN may have a multilayer structure or a single layer structure. For example, the window WIN may include multiple plastic films bonded to each other by an adhesive or may include a glass substrate and a plastic film bonded to each other by an adhesive.

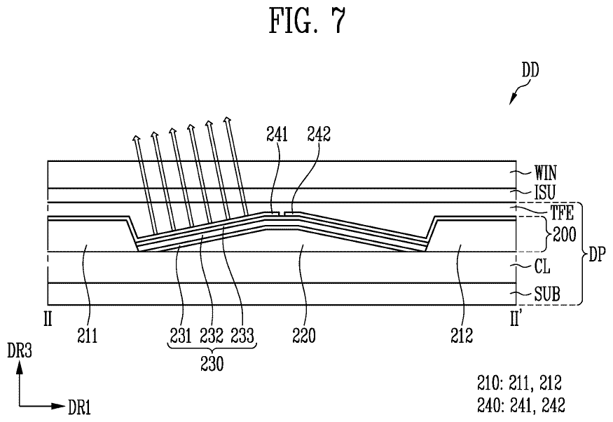

FIG. 7 is a view illustrating an embodiment of the display device DD of FIG. 6.

Referring to FIGS. 6 and 7, a normal direction of an inclined surface included in the fourth region R4 of the organic film layer 220 may be different from a normal direction of an inclined surface included in the fifth region R5 of the organic film layer 220. For example, as illustrated in FIG. 6, a normal direction of an inclined surface included in the fourth region R4 of the organic film layer 220 may face the left. The normal direction of the inclined surface included in the fifth region R5 of the organic film layer 220 may face the right.

In embodiments of the present disclosure, the display device DD may individually apply voltages to the first shield voltage layer 241 and the second shield voltage layer 242. For example, the display device DD may apply the same voltage to the first shield voltage layer 241 and the 31st electrode 231. In this case, light may not be emitted to the outside from the fourth region R4 of the third light-emitting element 230. For example, the display device DD may apply the same voltage to the second shield voltage layer 242 and the 31st electrode 231. In this case, light may not be emitted to the outside from the fifth region R5 of the third light-emitting element 230.

In embodiments of the present disclosure, while the same voltage is applied to the first shield voltage layer 241 and the 31st electrode 231, the second shield voltage layer 242 may be in a floating state. Accordingly, light may not be emitted to the outside from the fourth region R4 of the third light-emitting element 230, and light maybe emitted to the outside from the fifth region R5 of the third light-emitting element 230. In other words, light maybe emitted to the right of the organic film layer 220.

In contrast to this, while the same voltage is applied to the second shield voltage layer 242 and the 31st electrode 231, the first shield voltage layer 241 may be in a floating state. Accordingly, light may not be emitted to the outside from the fifth region R5 of the third light-emitting element 230, and light maybe emitted to the outside from the fourth region R4 of the third light-emitting element 230. In other words, light may be emitted to the left of the organic film layer 220.

As illustrated in FIGS. 6 and 7, light may be selectively emitted only from one of the fourth region R4 and the fifth region R5 of the third light-emitting element 230. Accordingly, a path of the light emitted from the display device DD may be controlled.

Although FIGS. 6 and 7 illustrate only the eighth sub-pixel SPXL8 as examples, the same description may be applied to the other sub-pixels. For example, in the seventh sub-pixel SPXL7 of FIG. 5, the first shield voltage layer and the second shield voltage layer may be respectively disposed on different inclined surfaces of the organic film layer. In response to voltages applied to the first shield voltage layer and the second shield voltage layer, the light-emitting element may emit light only in a selected direction. For example, in the ninth sub-pixel SPXL9 of FIG. 5, the first shield voltage layer and the second shield voltage layer may be respectively disposed on different inclined surfaces of the organic film layer. In response to voltages applied to the first shield voltage layer and the second shield voltage layer, the light-emitting element may emit light only in a selected direction. Accordingly, in the first mode, light-emitting elements of the seventh, eighth, and ninth sub-pixels SPXL7, SPXL8, and SPXL9 may be configured to emit light in a left direction in general to provide an image in the left direction. In the second mode, light-emitting elements of the seventh, eighth, and ninth sub-pixels SPXL7, SPXL8, and SPXL9 may be configured to emit light in a right direction in general to provide an image in the right direction.

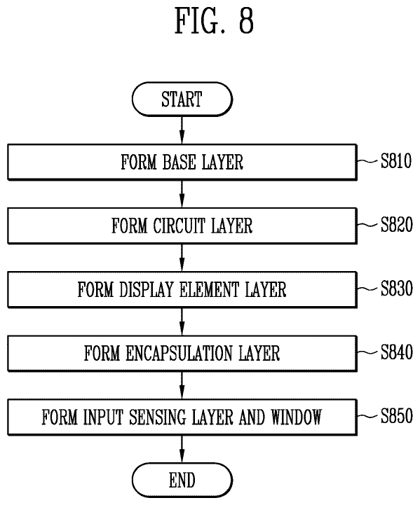

FIG. 8 is a flowchart illustrating a method of manufacturing the display device of FIG. 1.

Referring to FIGS. 3, 6, and 8, the base layer SUB may be formed in a step S810. The base layer SUB may be a polymer substrate, a plastic substrate, a glass substrate, a quartz substrate, or so on. The base layer SUB may be a transparent insulating substrate. The base layer SUB may be rigid. The base layer SUB may be flexible.

In a step S820, the circuit layer CL may be formed on the base layer SUB. The circuit layer CL may be disposed on the base layer SUB, the circuit layer CL may include a plurality of transistors, and the transistors may each include a control electrode, an input electrode, and an output electrode.

In an embodiment, the circuit layer CL may include a switching transistor and a drive transistor for driving the first and second light-emitting elements 130 and 140 of the display element layer 100.

In an embodiment, the circuit layer CL may include a switching transistor and a drive transistor for driving the third light-emitting element 230 of the display element layer 200.

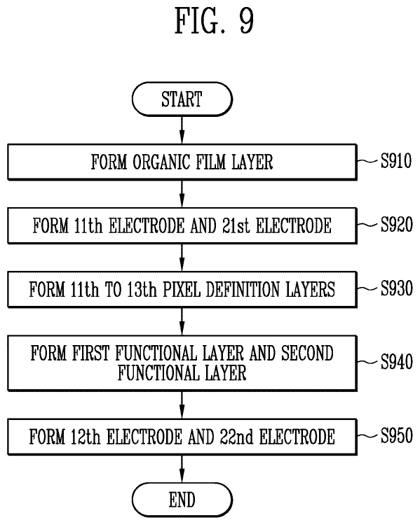

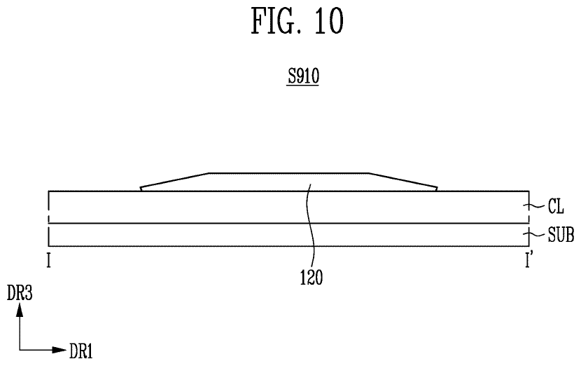

In a step S830, the display element layer 100 may be formed on the circuit layer CL. This will be described in detail below with reference to FIGS. 9 and 10.

In a step S840, the encapsulation layer TFE may be formed on the display element layer 100.

In an embodiment, the encapsulation layer TFE may be disposed on the display element layer 100 to seal the display element layer 100. The encapsulation layer TFE may protect the display element layer 200 from moisture and/or oxygen and may protect the display element layer 100 from foreign materials, such as dust particles.

In an embodiment, the encapsulation layer TFE may be disposed on the display element layer 200 to seal the display element layer 200. The encapsulation layer TFE may protect the display element layer 200 from moisture and/or oxygen and may protect the display element layer 200 from foreign materials, such as dust particles.

The encapsulation layer TFE may include at least one inorganic layer or at least one organic layer. The encapsulation layer TFE may have a structure in which organic layers and inorganic layers are alternately stacked. For example, the encapsulation layer TFE may have a structure in which an inorganic layer, an organic layer, and another inorganic layer are sequentially stacked.

In a step S850, the input sensing layer ISU and the window WIN may be formed on the encapsulation layer TFE.

FIG. 9 is a flowchart illustrating the step S830 of FIG. 8, according to an embodiment.

Referring to FIG. 3 and FIG. 9, in a step S910, the organic film layer 120 may be formed on the circuit layer CL.

In a step S920, the 11th electrode 131 and the 21st electrode 141 may be formed on the organic film layer 120. More specifically, the 11th electrode 131 and the 21st electrode 141 may be respectively formed on different inclined surfaces of the organic film layer 120.

In a step S930, the 11th to 13th pixel definition layers 111 to 113 may be formed.

In a step S940, the first functional layer 132 may be formed on the 11th electrode 131, and the second functional layer 142 may be formed on the 21st electrode 141.

In a step S950, the 12th electrode 133 may be formed on the first functional layer 132, and the 22nd electrode 143 may be formed on the second functional layer 142.

The method of manufacturing a display device according to an embodiment will be described in detail below with reference to FIGS. 10 to 14.

FIG. 10 is a view illustrating the step S910 of FIG. 9.

Referring to FIGS. 1 to 10, the organic film layer 120 may be disposed on the circuit layer CL.

The organic film layer 120 may be formed of an organic material. The organic film layer 120 may have a plurality of inclined surfaces. In embodiments, the organic film layer 120 may have a trapezoidal shape in cross-section.

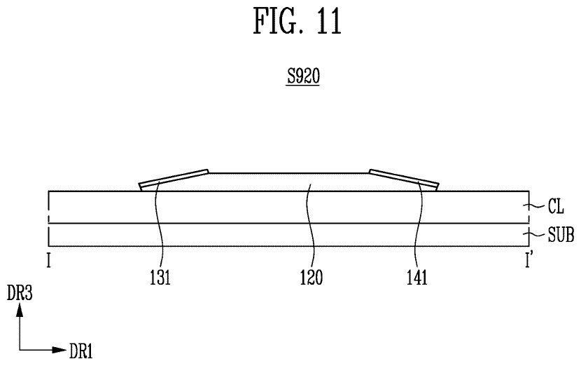

FIG. 11 is a view illustrating the step S920 of FIG. 9.

Referring to FIGS. 1 to 11, the first light-emitting element 130 may include the 11th electrode 131. The second light-emitting element 140 may include the 21st electrode 141.

The 11th electrode 131 may be disposed on one inclined surface among the inclined surfaces of the organic film layer 120. The 11th electrode 131 may be an anode electrode of the first light-emitting element 130.

The 21st electrode 141 may be disposed on another inclined surface of the organic film layer 120 other than the one inclined surface. The 21st electrode 141 may be an anode electrode of the second light-emitting element 140.

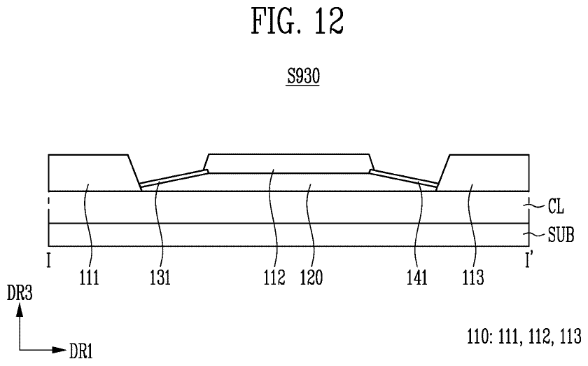

FIG. 12 is a view illustrating the step S930 of FIG. 9.

Referring to FIGS. 1 to 12, the 11th to 13th pixel-definition layers 111 to 113 may be formed.

The 11th to 13th pixel definition layers 111 to 113 may be formed by including a polyacrylate-based resin or a polyimide-based resin. In an embodiment, the pixel definition layers 110 may be formed by including an inorganic material. For example, the pixel definition layers 110 may be formed by including silicon nitride, silicon oxide, silicon oxynitride, or so on.

The 11th pixel definition layer 111 and the 13th pixel definition layer 113 may each have a trapezoidal shape in cross-section. For example, the 12th pixel definition layer 112 may have a rectangular shape in cross-section. However, the shapes of the 11th to 13th pixel definition layers 111 to 113, collectively the pixel definition layers 110, are not limited to the shapes illustrated in FIG. 12.

The 11th pixel definition layer 111 may be disposed on the circuit layer CL. The 13th pixel definition layer 113 may be disposed on the circuit layer CL. The 11th pixel definition layer 111 may be separated from the 13th pixel definition layer 113 in the first direction DR1. The 11th pixel definition layer 111 may be symmetrical to the 13th pixel definition layer 113 with the 12th pixel definition layer 112 therebetween.

In addition, the 12th pixel definition layer 112 may be disposed on the organic film layer 120.

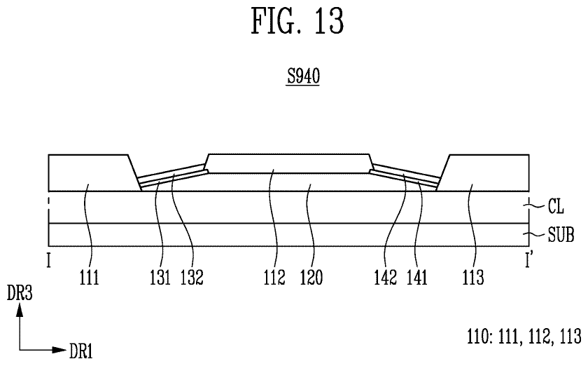

FIG. 13 is a view illustrating the step S940 of FIG. 9.

Referring to FIGS. 1 to 13, the first light-emitting element 130 may include the first functional layer 132, and the second light-emitting element 140 may include the second functional layer 142.

The first functional layer 132 may be formed on the 11th electrode 131, and the second functional layer 142 may be formed on the 21st electrode 141.

The first functional layer 132 and the second functional layer 142 may each include a hole transfer region, a light-emitting layer, and an electron transfer region that are sequentially stacked. The first light-emitting element 130 and the second light-emitting element 140 may emit light in the same wavelength range. The first light-emitting element 130 and the second light-emitting element 140 may emit light in a different wavelength range from the light-emitting elements included in the first and second sub-pixels SPXL1 and SPXL2 of FIG. 2. Similarly, the first light-emitting element 130 and the second light-emitting element 140 may emit light in a different wavelength range from the light-emitting elements included in the fifth and sixth sub-pixels SPXL5 and SPXL6 of FIG. 2.

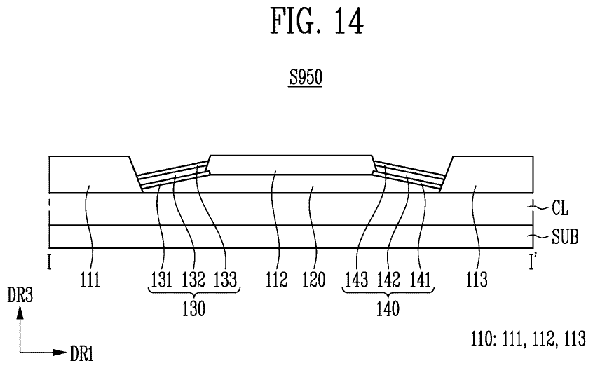

FIG. 14 is a view illustrating step S950 of FIG. 9.

Referring to FIGS. 1 to 14, the first light-emitting element 130 may include the 12th electrode 133, and the second light-emitting element 140 may include the 22nd electrode 143.

The 12th electrode 133 may be disposed on the first functional layer 132. The 12th electrode 133 may be a cathode electrode of the first light-emitting element 130.

The 22nd electrode 143 may be disposed on the second functional layer 142. The 22nd electrode 143 may be a cathode electrode of the second light-emitting element 140.

In embodiments of the present disclosure, the display device DD may select either the first light-emitting element 130 or the second light-emitting element 140 to emit light. For example, the second light-emitting element 140 may emit light, and the first light-emitting element 130 may not emit light. Accordingly, light may be emitted to the right of the organic film layer 120, and light may not be emitted to the left of the organic film layer 120. For example, the first light-emitting element 130 may emit light, and the second light-emitting element 140 may not emit light. Accordingly, light may be emitted to the left of the organic film layer 120, and light may not be emitted to the right of the organic film layer 120.

As illustrated in FIGS. 3 and 4, the first light-emitting element 130 and the second light-emitting element 140 may be respectively disposed on different inclined surfaces of the organic film layer 120. In addition, only one of the first light-emitting element 130 and the second light-emitting element 140 may selectively emit light. Accordingly, a path of the light emitted from the display device DD may be controlled.

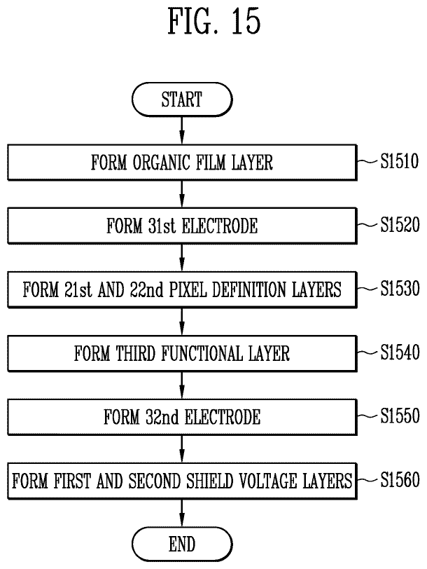

FIG. 15 is a flowchart illustrating the step S830 of FIG. 8 according to an embodiment.

Referring to FIG. 6 and FIG. 15, in a step S1510, the organic film layer 220 may be formed on the circuit layer CL. The organic film layer 220 may be formed of an organic material. The organic film layer 220 may have a plurality of inclined surfaces. In embodiments, the organic film layer 220 may have a trapezoidal shape in cross-section.

In a step S1520, the 31st electrode 231 may be formed on the organic film layer 220.

The third light-emitting element 230 may include the 31st electrode 231. The 31st electrode 231 may be an anode electrode of the third light-emitting element 230.

The 31st electrode 231 may be disposed on the entire inclined surfaces of the organic film layer 220.

In a step S1530, the 21st and 22nd pixel definition layers 211 and 212 may be formed. The 21st and 22nd pixel definition layers 211 and 212 may each be formed by including a polyacrylate-based resin or a polyimide-based resin. In an embodiment, the 21st and 22nd pixel definition layers 211 and 212 may each be formed by including an inorganic material. For example, the 21st and 22nd pixel definition layers 211 and 212 may each be formed by including silicon nitride, silicon oxide, silicon oxynitride, or so on. The 21st pixel definition layer 211 and the 22nd pixel definition layer 212 may each have a trapezoidal shape in cross-section.

In a step S1540, the third light-emitting element 230 may include the third functional layer 232. The third functional layer 232 may be formed on the 31st electrode 231.

The third functional layer 232 may include a hole transfer region, a light-emitting layer, and an electron transfer region that are sequentially stacked.

In a step S1550, the third light-emitting element 230 may include the 32nd electrode 233. The 32nd electrode 233 may be formed on the third functional layer 232.

In a step S1560, the shield voltage layer 240 may be formed on the third light-emitting element 230. The shield voltage layer 240 may include an inorganic material and a transparent electrode. A part of the first shield voltage layer 241 may be disposed on an inclined surface included in the fourth region R4 of the organic film layer 220. A part of the second shield voltage layer 242 may be disposed on an inclined surface included in the fifth region R5 of the organic film layer 220.

While the same voltage is applied to the first shield voltage layer 241 and the 31st electrode 231, the second shield voltage layer 242 may be in a floating state. Accordingly, light may not be emitted to the outside from the fourth region R4 of the third light-emitting element 230, and light may be emitted to the outside from the fifth region R5 of the third light-emitting element 230. In other words, light may be emitted in general to the right of the organic film layer 220.

In contrast to this, while the same voltage is applied to the second shield voltage layer 242 and the 31st electrode 231, the first shield voltage layer 241 may be in a floating state. Accordingly, light may not be emitted to the outside from the fifth region R5 of the third light-emitting element 230, and light may be emitted to the outside from the fourth region R4 of the third light-emitting element 230. In other words, light may be emitted in general to the left of the organic film layer 220.

A display device according to an embodiment is applicable to various types of electronic devices. In an embodiment, an electronic device includes the above-described display device and may further include other modules or devices having additional functions in addition to the display device.

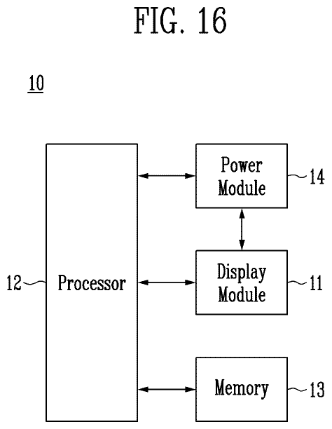

FIG. 16 is a block diagram of an electronic device according to an embodiment. Referring to FIG. 16, the electronic device 10 may include a display module 11, a processor 12, a memory 13, and a power module 14.

The processor 12 may include at least one of a central processing unit (CPU), an application processor (AP), a graphic processing unit (GPU), a communication processor (CP), an image signal processor (ISP), and a controller.

The memory 13 may store data and/or information used to operate the processor 12 or the display module 11. When the processor 12 executes an application stored in the memory 13, image data signals and/or input control signals may be transferred to the display module 11. The display module 11 may process the provided signals and output image information on a display screen.

The power module 14 may include a power supply module, such as a power adapter or a battery device, and a power conversion module. The power conversion module converts power supplied by the power supply module and generates power to operate the electronic device 10.

At least one of the above-described components of the electronic device 10 may be included in the display device according to embodiments as described above. In addition, in terms of functionality, some of the individual modules included in one module may be included in the display device and others may be provided separately from the display device. For example, the display module 11 is included in the display device, whereas the processor 12, the memory 13, and the power module 14 are not included in the display device and are instead provided separately in the electronic device 10.

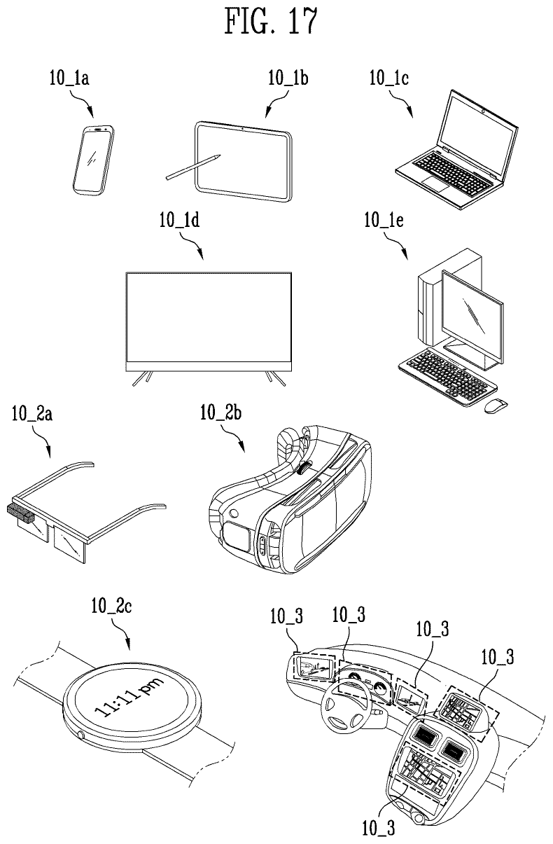

FIG. 17 shows schematic views of various embodiments of an electronic device.

Referring to FIG. 17, various types of electronic devices to which embodiments of a display device are applied may include an electronic device to display images such as a smartphone 10_1a, a tablet PC 10_1b, a laptop computer 10_1c, a television (TV) 10_1d, and a desktop monitor 10_1e, a wearable electronic device including a display module such as smart glasses 10_2a, a head-mounted display (HMD) 10_2b, and a smart watch 10_2c, and an automotive electronic device 10_3 including a display module such as a center information display (CID) disposed at the instrument cluster, the center fascia, and the dashboard of a vehicle, and a room mirror display.

Although specific embodiments and application examples are described herein, other embodiments and modifications may be derived from the above description. Therefore, the idea of the present disclosure is not limited to the embodiments and extends to the claims described below, various obvious modifications, and equivalents.

What is claimed is:

1. A display device comprising:
an organic film layer having a plurality of inclined surfaces including a first inclined surface and a second inclined surface;
a first light-emitting element disposed on the first inclined surface; and
a second light-emitting element disposed on the second inclined surface,
wherein the first light-emitting element and the second light-emitting element emit light of the same color, and
the first light-emitting element is symmetrical to the second light-emitting element with respect to a first pixel definition layer disposed on the organic film layer.

2. The display device of claim 1, wherein,
the organic film layer has a trapezoidal shape in cross-section.

3. The display device of claim 2, wherein,
a normal direction of the first inclined surface of the organic film layer is different from a normal direction of the second inclined surface of the organic film layer.

4. The display device of claim 1, wherein,
in a period in which the first light-emitting element emits the light, the second light-emitting element does not emit the light.

5. The display device of claim 1, wherein,
the first light-emitting element is included in a first sub-pixel, and
the second light-emitting element is included in a second sub-pixel different from the first sub-pixel.

6. A display device comprising:
an organic film layer having a plurality of inclined surfaces including a first inclined surface and a second inclined surface;
a first light-emitting element disposed on the first inclined surface and the second inclined surface;
a first shield voltage layer disposed on a first area of the first light-emitting element; and
a second shield voltage layer disposed on a second area of the first light-emitting element,
wherein voltages are individually applied to the first shield voltage layer and the second shield voltage layer.

7. The display device of claim 6, wherein,
the organic film layer has a trapezoidal shape in cross-section.

8. The display device of claim 6, further comprising:
a first pixel definition layer and a second pixel definition layer,
wherein the first shield voltage layer is disposed on the first pixel definition layer and the first area of the first light-emitting element, and
the second shield voltage layer is disposed on the second pixel definition layer and the second area of the first light-emitting element.

9. The display device of claim 8, wherein,
a normal direction of an upper surface of the first shield voltage layer disposed on the first area of the first light-emitting element is different from a normal direction of an upper surface of the second shield voltage layer disposed on the second area of the first light-emitting element.

10. The display device of claim 6, wherein,
the first light-emitting element includes a first electrode disposed on the organic film layer, and
the same voltage is applied to the first electrode and the first shield voltage layer, and the second shield voltage layer is in a floating state.

11. An electronic device comprising:
an organic film layer having a plurality of inclined surfaces including a first inclined surface and a second inclined surface;
a first light-emitting element disposed on the first inclined surface; and
a second light-emitting element disposed on the second inclined surface,
wherein the first light-emitting element and the second light-emitting element emit light of the same color, and
the first light-emitting element is symmetrical to the second light-emitting element with respect to a first pixel definition layer disposed on the organic film layer.

12. The electronic device of claim 11, wherein,
the organic film layer has a trapezoidal shape in cross-section.

13. The electronic device of claim 12, wherein,
a normal direction of the first inclined surface of the organic film layer is different from a normal direction of the second inclined surface of the organic film layer.

14. The electronic device of claim 11, wherein,
in a period in which the first light-emitting element emits the light, the second light-emitting element does not emit the light.

15. The electronic device of claim 11, wherein,
the first light-emitting element is included in a first sub-pixel, and
the second light-emitting element is included in a second sub-pixel different from the first sub-pixel.
